(19) United States
(12) Patent Application Publication
(10) Pub. No.: US 2004/0195663 A1
(43) Pub. Date: Oct. 7, 2004

(54) Metal support (leadframe) for the bonding of electrical or optoelectronic components

(76) Inventors: Hans Hurt, Regensburg (DE); Frank Weberpals, Regensburg (DE)

Correspondence Address: ESCHWEILER & ASSOCIATES, LLC, NATIONAL CITY BANK BUILDING, 629 EUCLID AVE., SUITE 1210, CLEVELAND, OH, 44114, US

(21) Appl. No.: 10/773,975

(22) Filed: Feb. 6, 2004

(30) Foreign Application Priority Data
Feb. 7, 2003 (DE) 203 02 356.0

(51) Int. Cl. H01L 23/495

(52) U.S. Cl. 257/676

(57) ABSTRACT

A metal support or leadframe for the bonding of electrical or optoelectronic components is provided. The leadframe includes a multiplicity of contact legs, that can respectively be connected to one end of a bonding wire for the bonding of a component at a bonding region. At least one electrically nonconducting structure is provided that mechanically interconnects at least two of the contact legs.

### REFERENCE TO RELATED APPLICATIONS

This application claims the benefit of the priority date of German application DE 203 02 356.0, filed on Feb. 7, 2003, the contents of which are herein incorporated by reference in their entirety.

### FIELD OF THE INVENTION

The invention relates to a metal support (leadframe) for the bonding of electrical or optoelectronic components.

### BACKGROUND OF THE INVENTION

There are known metal supports which serve for the bonding of an electrical or electronic component and, for this purpose, provide a multiplicity of contact legs, by means of which the component can be electrically bonded. In this case, bonding wires are respectively placed between the contact legs of the metal support and contact pads of the component. Such metal supports are also referred to as leadframes.

The finished arrangement comprising the leadframe, the component and the bonding wires is usually encapsulated with an encapsulating material. For example, DE 199 09 242 A1 discloses an arrangement in which a leadframe is positioned with an optoelectronic transducer in a module package, which is open on one side, and encapsulated with a translucent, moldable material. Light is coupled in or out via an optical fiber, which is coupled to a connecting piece of the module package. On the leadframe there is also the driving device or receiving device for the optoelectronic transducer. The contact legs of the leadframe protrude from the package on the open side.

There is then the problem that the bonding connections can be damaged during the production process on account of oscillations and vibrations of the leadframe. This risk exists in particular at a point in time of the production process at which the finished arrangement has not yet been encapsulated with an encapsulating material. In order to avoid damage to the bonding connections caused by oscillations and vibrations as much as possible during the production process, the bonding connections are placed as far away as possible from the end of the leadframe and, however, consequently at the same time also far away from the component (for example driver IC) to be bonded.

Such a measure involves the disadvantage that the bonding connections are particularly long and are accordingly susceptible.

### SUMMARY OF THE INVENTION

The following presents a simplified summary in order to provide a basic understanding of one or more aspects of the invention. This summary is not an extensive overview of the invention, and is neither intended to identify key or critical elements of the invention, nor to delineate the scope thereof. Rather, the primary purpose of the summary is to present some concepts of the invention in a simplified form as a prelude to the more detailed description that is presented later.

The present invention is based on the object of providing a metal support (leadframe) which is distinguished by advantageous mechanical properties and, in particular, allows the reliable realization of short and resistant bonding connections.

The way in which the object is achieved according to the invention is accordingly that at least two contact legs of the metal support (leadframe) are interconnected by at least one electrically nonconducting structure. As a result, a mechanical stabilization of the leadframe is achieved: the susceptibility to oscillations and vibrations is greatly reduced and relative movements of the contact legs in relation to one another are ruled out. The mechanical stability increased in this way provides the possibility of placing the bonding connections at the ends of the contact legs, that is adjacent the component to be bonded. As a result, short, and therefore resistant, bonding connections can be realized.

In a preferred configuration of the invention, the nonconducting structure comprises an injection-moldable plastics material, with which at least two contact legs are encapsulated. Any desired injection-moldable plastic may be used here, for example PBT (polybutylene terephthalate). In this way, the nonconducting structure can be provided in a simple, low-cost and effective way.

The nonconducting structure is preferably formed as at least one web, which respectively interconnects at least two contact legs. The web in this case advantageously runs substantially perpendicularly to the longitudinal direction of the contact legs, i.e. transverse struts are provided between the contact legs, which effectively reduces vibrations.

In an advantageous configuration, at least most of the bonding regions of the contact legs are arranged in the region of the ends of the contact legs that lie adjacent a component to be bonded, so that short bonding connections can be realized. This is made possible specifically by the stabilization of the leadframe as provided by the invention.

Numerous arrangements of nonconducting structures in a leadframe are conceivable. For example, a number of web-shaped structures arranged next to one another and/or parallel to one another and/or offset from one another. The web-shaped structures may in this case be of different lengths, so that, if appropriate, a multiplicity of contact legs are interconnected by one structure.

The thermal expansion of the nonconducting structure is preferably adapted to the thermal expansion of an encapsulating compound with which the metal support and the component are encapsulated after assembly has been completed. This achieves the effect that the connection of the nonconducting structure to the surrounding encapsulating compound is temperature-resistant and no internal discontinuities occur. The physical properties of the nonconducting structure and the surrounding encapsulating compound are also otherwise adapted to one another as well as possible, for example with regard to the adhesion coefficient.

The following description and annexed drawings set forth in detail certain illustrative aspects and implementations of the invention. These are indicative of only a few of the various ways in which the principles of the invention may be employed.

### BRIEF DESCRIPTION OF THE DRAWINGS

The invention is explained in more detail below on the basis of an exemplary embodiment with reference to the figures of the drawing, in which:

FIG. 1 shows a leadframe with a plurality of plastic webs, which mechanically interconnect individual legs of the leadframe, and

FIG. 2 shows a leadframe according to the prior art.

### DETAILED DESCRIPTION OF THE INVENTION

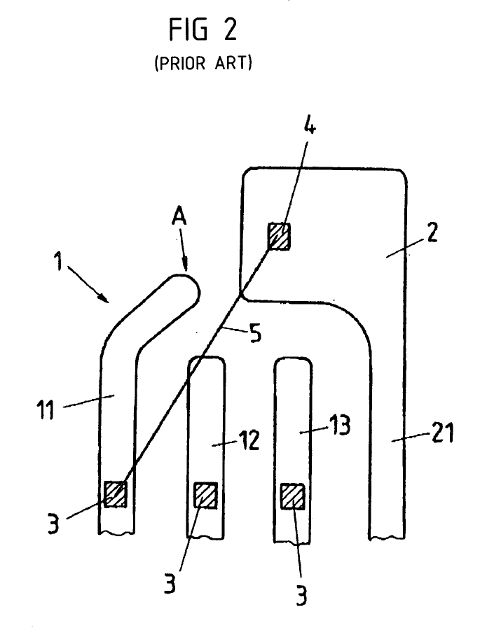

A conventional metal support 1, represented in FIG. 2, for the bonding of electrical or optoelectronic components (leadframe) has a multiplicity of contact legs or leadframe legs 11, 12, 13. The end A of the contact legs 11, 12, 13 that is adjacent a component to be bonded is represented. The other end extends in the direction of the outer edge of the leadframe for the further bonding of the contact legs, for instance to the electrical leads of a printed circuit board.

A component to be bonded is mounted on a receiving area 2 of the leadframe 1. The component (not separately represented) may be any desired electrical or optoelectronic component. For example, it is an optoelectronic module with a laser diode and/or a receiving diode for the coupling in and out of optical signals, which is arranged in a package, as described in DE 199 09 242 A1, and which is hereby incorporated by reference in its entirety. The receiving area 2 has an attachment arm 21, which likewise extends to the outer edge of the leadframe.

The individual leadframe legs 11, 12, 13, the receiving area 2 and the attachment arm 21 are composed of a conducting material and are produced in a way known per se from a metal foil, for example by stamping or etching. Alternatively, the leadframe 1 exclusively comprises the contact legs 11, 12, 13, and the receiving area 2 for the component is provided as a separate part.

The leadframe legs 11, 12, 13 are of a certain width, so that a contact region 3 (bonding pad) for the bonding of one end of a bonding wire can be respectively realized on them. However, it is similarly possible that the entire leadframe surface can be bonded without additional special preparations, for example by complete silver-plating. The other end of the bonding wire is connected to a contact pad 4, which is assigned to the component to be bonded and is located on the receiving area 2, a further support or on the component directly. For the sake of providing an overview, only one bonding wire 5 is represented in FIG. 2. The further contact legs 12, 13 are likewise connected by means of bonding wires to a component to be bonded.

During the production process, oscillations and vibrations which can lead to damage to the bonding connections 5 act on the leadframe legs 11, 12, 13. The problem occurs in particular in a phase of the production process in which as yet no final encapsulation of the completely assembled arrangement with an encapsulating material takes place. After such encapsulation, the bonding connections are protected. In order to avoid damage to the bonding connections before the encapsulation, the bonding connections are placed, as represented in FIG. 2, as far away as possible from the leadframe end A, i.e. as far away as possible from the component to be bonded and as close as possible to the outer edge of the leadframe, where the oscillating load is lowest.

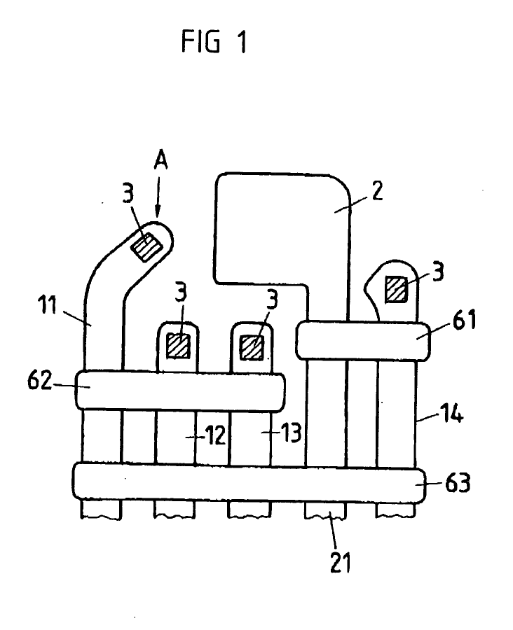

FIG. 1 shows an arrangement according to the invention. According to this, at least two leadframe legs 11, 12, 13, 14 are respectively connected to a plastic structure 61, 62, 63, which in the exemplary embodiment represented is in each case a web of an electrically nonconducting, injection-moldable material running transversely to the longitudinal direction of the plastic legs. For producing the plastic webs 61, 62, 63, the individual contact legs 11, 12, 13, 14 are encapsulated in a simple way with a suitable plastics material, for instance PBT (polybutylene terephthalate). Subsequently, the bonding between the contact legs 11, 12, 13, 14 and the assigned contact pads of a component to be bonded (not represented), which is arranged on a receiving area 2, takes place.

The transverse webs 61, 62, 63 have the effect of a considerable mechanical stabilization of the leadframe legs 11, 12, 13, 14 with respect to oscillations and relative movements in relation to one another. This makes it possible to realize the bonding connections at the ends A of the leadframe legs 11, 12, 13, 14. The contact pads 3 are accordingly respectively arranged at the ends of the leadframe legs 11, 12, 13, 14.

As can be seen from FIG. 1, the individual leadframe legs may be of different lengths and also run at different distances from the component to be bonded or its receiving area 2. The connecting web 61 at the top right in the arrangement of FIG. 1 is connected to the attachment arm 21 of the receiving area 2.

The encapsulation of the finished arrangement takes place with an encapsulating material, for example a transparent optical resin.

The encapsulated arrangement is preferably arranged in a package in such a way that the plastic webs 61, 62, 63 are located inside the package and are not visible from the outside.

The invention is not restricted in its configuration to the exemplary embodiment represented above. In principle, any desired configurations of leadframes and connecting elements may be provided. All that is essential for the invention is that at least two contact legs of the leadframe are mechanically interconnected by means of an electrically nonconducting structure, it also being possible for such a contact leg to be an attachment arm of a receiving structure.

Although the invention has been illustrated and described with respect to one or more implementations, alterations and/or modifications may be made to the illustrated examples without departing from the spirit and scope of the appended claims. In addition, while a particular feature of the invention may have been disclosed with respect to only one of several implementations, such feature may be combined with one or more other features of the other implementations as may be desired and advantageous for any given or particular application. Furthermore, to the extent that the terms “including”, “includes”, “having”, “has”, “with”, or variants thereof are used in either the detailed description and the claims, such terms are intended to be inclusive in a manner similar to the term “comprising”.

1. A metal support for the bonding of electrical or optoelectronic components with a multiplicity of contact legs, that can respectively be connected to one end of a bonding wire for the bonding of a component at a bonding region, comprising at least one electrically nonconducting structure that mechanically interconnects at least two contact legs.

2. The metal support as claimed in claim 1, wherein the nonconducting structure comprises an injection-moldable plastic material, with which at least two contact legs are encapsulated.

3. The metal support as claimed in claim 1, wherein the nonconducting structure comprises at least one web that respectively interconnects at least two contact legs.

4. The metal support as claimed in claim 3, wherein the web runs substantially perpendicularly to the longitudinal direction of the contact legs.

5. The metal support as claimed in claim 1, wherein at least most of the bonding regions of the contact legs are arranged in a region at the ends of the contact legs that lie adjacent a component to be bonded.

6. The metal support as claimed in claim 1, wherein the nonconducting structure comprises a number of web-shaped structures present next to one another or parallel to one another or offset from one another.

7. The metal support as claimed in claim 6, wherein the web-shaped structures are of different lengths.

8. The metal support as claimed in claim 1, wherein the thermal expansion of the nonconducting structure is adapted to the thermal expansion of an encapsulating compound with which the metal support and the component are encapsulated after assembly has been completed.

9. A leadframe, comprising:
a receiving pad for placement of an electrical or optoelectronic component thereon;
a plurality of electrically conducting leadframe legs each having a first end extending toward the receiving pad, and a second end extending away therefrom; and
an electrically nonconducting structure traversing and mechanically interconnecting at least two of the leadframe legs.

10. The leadframe of claim 9, further comprising a bonding pad region at the first end of each of the plurality of lead frame legs.

11. The leadframe of claim 9, further comprising a bonding pad region located near the first end of each of the plurality of lead frame legs, wherein the bonding pad regions of the at least two leadframe legs interconnected by the nonconducting structure are located between the first end and the nonconducting structure.

12. The leadframe of claim 9, wherein the nonconducting structure comprises an injection-moldable plastic material.

13. The leadframe of claim 12, wherein the plastic material consists of polybutylene terephthalate.

14. The leadframe of claim 9, wherein the nonconducting structure comprises at least one web that respectively interconnects at least two leadframe legs.

15. The leadframe of claim 14, wherein the web runs substantially perpendicularly to the longitudinal direction of the leadframe legs.

16. The metal support as claimed in claim 9, wherein the nonconducting structure comprises a number of web-shaped structures present next to one another or parallel to one another or offset from one another.

17. The leadframe of claim 16, wherein the web-shaped structures are of different lengths.

18. The leadframe of claim 9, wherein the thermal expansion of the nonconducting structure is adapted to the thermal expansion of an encapsulating compound with which the leadframe and the component are encapsulated after assembly has been completed.
